(19) United States
(12) Patent Application Publication
(10) Pub. No.: US 2024/0332778 A1
(43) Pub. Date: Oct. 3, 2024

(54) DIRECTIONAL COUPLER, RADIO FREQUENCY MODULE, AND COMMUNICATION APPARATUS

(71) Applicant: Murata Manufacturing Co., Ltd., Kyoto (JP)

(72) Inventors: Kazuhito OSAWA, Kyoto (JP); Ryangsu KIM, Kyoto (JP); Kenta SEKI, Kyoto (JP)

(21) Appl. No.: 18/742,270

(22) Filed: Jun. 13, 2024

Related U.S. Application Data
(63) Continuation of application No. PCT/JP2022/047434, filed on Dec. 22, 2022.

(30) Foreign Application Priority Data
Dec. 27, 2021 (JP) 2021-213283

(51) Int. Cl. H01P 5/18; H03H 7/18; H04B 1/44

(52) U.S. Cl. CPC H01P 5/18; H03H 7/18; H04B 1/44

(57) ABSTRACT

A directional coupler includes a main line, a first sub line, a second sub line, a termination circuit, a first phase shifter circuit, a first selector switch, and a second selector switch. The termination circuit terminates one of the first sub line and the second sub line. The first phase shifter circuit is disposed on a first signal path between the first sub line and the second sub line. The first selector switch performs switching between connection and non-connection between the first sub line and the first phase shifter circuit. The second selector switch performs switching between connection and non-connection between the first phase shifter circuit and the second sub line.

### CROSS REFERENCE TO RELATED APPLICATION

This is a continuation of International Application No. PCT/JP2022/047434 filed on Dec. 22, 2022 which claims priority from Japanese Patent Application No. 2021-213283 filed on Dec. 27, 2021. The contents of these applications are incorporated herein by reference in their entireties.

### BACKGROUND ART

### Technical Field

The present disclosure relates to a directional coupler, a radio frequency module, and a communication apparatus.

A directional coupler described in Patent Document 1 includes a main line, two sub lines (first and second sub lines), and a switch circuit (a first selector switch and a second selector switch). In this directional coupler, when a first signal in a higher frequency band that flows through the main line is extracted from a sub line, a used sub line is a sub line composed of one of the first sub line and the second sub line. When a second signal in a lower frequency band that flows through the main line is extracted, a used sub line is a sub line in which the first sub line and the second sub line are connected in series.

Patent Document 1: Japanese Unexamined Patent Application Publication No. 2021-27426

### BRIEF SUMMARY

In the directional coupler described in Patent Document 1, in a case where the first signal and the second signal simultaneously flow through the main line, part of the first signal (a detection-excluded signal) flowing through the main line leaks to the sub line when the second signal (a detection-targeted signal) flowing through the main line is extracted from the sub line, and thereby loss occurs in the first signal flowing through the main line in some cases.

The present disclosure provides a directional coupler, a radio frequency module, and a communication apparatus that are enabled to prevent loss from occurring in a detection-excluded signal when part of a detection-targeted signal flowing through a main line is extracted from a sub line, the detection-excluded signal flowing through the main line simultaneously with the detection-targeted signal.

### Solution to Problem

A directional coupler according to an aspect of the present disclosure includes a main line, a first sub line, a second sub line, a termination circuit, a first phase shifter circuit, a first selector switch, and a second selector switch. The termination circuit terminates one of the first sub line and the second sub line. The first phase shifter circuit is disposed on a first signal path between the first sub line and the second sub line. The first selector switch performs switching between connection and non-connection between the first sub line and the first phase shifter circuit. The second selector switch performs switching between connection and non-connection between the first phase shifter circuit and the second sub line.

A radio frequency module according to an aspect of the present disclosure includes a directional coupler, an antenna terminal, a plurality of filters, and an antenna switch. The antenna switch performs switching between connection and non-connection between a third signal path reaching the antenna terminal and each of the plurality of filters. The main line of the directional coupler forms a partial section of the third signal path.

A communication apparatus according to an aspect of the present disclosure includes a radio frequency module and a signal processing circuit. The signal processing circuit is connected to the radio frequency module and performs signal processing of a radio frequency signal.

The directional coupler, the radio frequency module, and the communication apparatus according to the aspects above of the present disclosure can enable loss to be prevented from occurring in a detection-excluded signal when part of a detection-targeted signal flowing through the main line is extracted from the sub line, the detection-excluded signal flowing through the main line simultaneously with the detection-targeted signal.

### BRIEF DESCRIPTION OF THE DRAWINGS

FIG. 1 is a circuit diagram of a directional coupler according to Embodiment 1 in a first mode.

FIG. 2 is a circuit diagram of the directional coupler described above in a second mode.

FIG. 3 is a circuit diagram of a phase shifter circuit of the directional coupler described above.

FIG. 4 is a circuit diagram of a directional coupler in the first mode in a comparative example.

FIG. 5 is a circuit diagram of the directional coupler in the second mode in the comparative example.

FIG. 6 is an explanatory view explaining insertion losses in the directional coupler in the comparative example.

FIG. 7 is an explanatory view explaining insertion losses of detection-excluded signals of the directional coupler in Embodiment 1.

FIG. 8 is a circuit diagram of a phase shifter circuit in Modification 2 of Embodiment 1.

FIG. 9 is a circuit diagram of a phase shifter circuit in Modification 3 of Embodiment 1.

FIG. 10 is another circuit diagram of the phase shifter circuit in Modification 3 of Embodiment 1.

FIG. 11 is a circuit diagram of a termination circuit in Modification 4 of Embodiment 1.

FIG. 12 is an exploded perspective diagram of a directional coupler in Modification 5 of Embodiment 1.

FIG. 13 is a perspective plan view of part of the directional coupler described above in Modification 5.

FIG. 14 is a circuit diagram of a directional coupler according to Embodiment 2.

FIG. 15 is a view of the configuration of an example of a communication apparatus according to Embodiment 3.

### DETAILED DESCRIPTION

Hereinafter, a directional coupler, a radio frequency module, and a communication apparatus according to embodiments will be described with reference to the drawings. Component sizes, thicknesses, and dimensional relationships described in the specifications and the drawings are each an example, and the components are not limited to examples described in the specifications and the drawings.

### Embodiment 1

### (1) Circuit Configuration of Directional Coupler

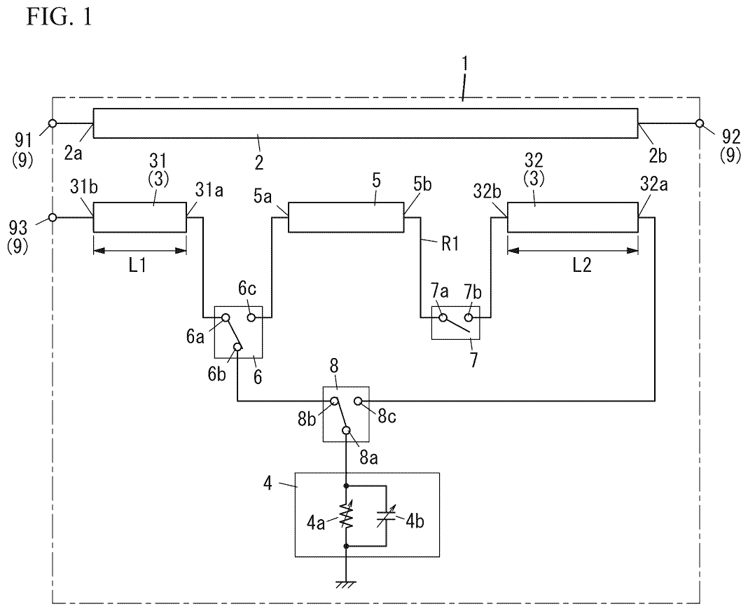

The circuit configuration of a directional coupler 1 according to Embodiment 1 will be described with reference to FIG. 1.

The directional coupler 1 is used for, for example, a radio frequency module of a communication apparatus. As illustrated in FIG. 1, the directional coupler 1 is a device that extracts, as a detection signal, part of a radio frequency signal flowing through a partial section (a main line 2) of a signal path in the radio frequency module, from a sub line 3 electromagnetically coupled to the main line 2. Monitoring the detection signal enables the radio frequency signal flowing through the main line 2 to be monitored. The directional coupler 1 in Embodiment 1 is configured to support signals in a plurality of frequency bands by allowing the line length of the sub line 3 to be changed between a plurality of lengths (for example, two lengths). The directional coupler 1 in Embodiment 1 is configured to be able to prevent loss from occurring in a detection-excluded signal when part of a detection-targeted signal flowing through the main line 2 is extracted from the sub line 3, the detection-excluded signal flowing through the main line 2 simultaneously with the detection-targeted signal. Hereinafter, the directional coupler 1 will be described in detail.

As illustrated in FIG. 1, the directional coupler 1 includes the main line 2, the sub line 3, a termination circuit 4, a first phase shifter circuit 5, a first selector switch 6, a second selector switch 7, and an end switch 8. The directional coupler 1 further includes a first connection terminal 91, a second connection terminal 92, and a third connection terminal 93.

The first to third connection terminals 91 to 93 are terminals connectable to an external circuit (not illustrated). The first connection terminal 91 functions as an input terminal that inputs a radio frequency signal from, for example, the external circuit described above to the main line 2. The second connection terminal 92 functions as an output terminal that outputs a radio frequency signal from the main line 2 to, for example, the external circuit described above. The third connection terminal 93 functions as a coupling terminal that outputs, to, for example, the external circuit described above, a detection signal extracted from the sub line 3.

The main line 2 is a line through which a detection target radio frequency signal flows. The main line 2 has a first end 2a and a second end 2b that are the ends, in a longitudinal direction, of the main line 2. The first end 2a of the main line 2 is connected to the first connection terminal 91. The second end 2b of the main line 2 is connected to the second connection terminal 92.

The sub line 3 is electromagnetically coupled to the main line 2 and is a line for extracting part of the radio frequency signal flowing through the main line 2, as a detection signal. The sub line 3 has a first sub line 31 and a second sub line 32.

The first sub line 31 has a first end 31a and a second end 31b that are the ends, in the longitudinal direction, of the first sub line 31. The first end 31a of the first sub line 31 is connected to a common terminal 6a (described later) of the first selector switch 6. The second end 31b of the first sub line 31 is connected to the third connection terminal 93. The first sub line 31 is electromagnetically coupled to the main line 2.

The second sub line 32 has a first end 32a and a second end 32b that are the ends, in the longitudinal direction, of the second sub line 32. The first end 32a of the second sub line 32 is connected to a selection terminal 8c (described later) of the end switch 8. The second end 32b of the second sub line 32 is connected to a terminal 7b (described later) of the second selector switch 7. Like the first sub line 31, the second sub line 32 is electromagnetically coupled to the main line 2.

The first sub line 31 and the second sub line 32 are arranged in the longitudinal direction of the main line 2. A length L1 of the first sub line 31 and a length L2 of the second sub line 32 are different from each other. In Embodiment 1, the length L2 of the second sub line 32 is longer than the length L1 of the first sub line 31. However, the length L2 of the second sub line 32 may be shorter than the length L1 of the first sub line 31. In addition, the length L1 of the first sub line 31 and the length L2 of the second sub line 32 may be the same as each other.

In a first mode, of the first sub line 31 and the second sub line 32, only the first sub line 31 is used as the sub line 3. In the first mode, of the first sub line 31 and the second sub line 32, only the second sub line 32 may be used as the sub line 3. In a second mode, both of the first sub line 31 and the second sub line 32 are used as the sub line 3. In more detail, in the second mode, a series circuit in which the first phase shifter circuit 5 is connected between the first sub line 31 and the second sub line 32 is used as the sub line 3.

The termination circuit 4 is a circuit to terminate one of the first sub line 31 and the second sub line 32. In more detail, in the first mode, the termination circuit 4 terminates the first sub line 31. In the second mode, the termination circuit 4 terminates the second sub line 32 in a series circuit in which the first sub line 31, the first phase shifter circuit 5, and the second sub line 32 connected in series in this order. The termination circuit 4 has circuit components having variable characteristic values (for example, a variable resistor 4a and a variable capacitor 4b). A characteristic value of a circuit component is a value that specifies a characteristic regarding a function of the circuit component. The characteristic value is a resistance value if the circuit component is a variable resistor, is a capacitance value if the circuit component is a capacitor, and is an inductance if the circuit component is an inductor. The variable resistor 4a is connected between a common terminal 8a of the end switch 8 and the ground. The variable capacitor 4b is connected to the variable resistor 4a in parallel. That is, the variable capacitor 4b is also connected between the common terminal 8a of the end switch 8 and the ground.

Controlling the resistance value of the variable resistor 4a and the capacitance value of the variable capacitor 4b enables a characteristic (for example, directivity) of the directional coupler 1 to be controlled. In more detail, in Embodiment 1, in the second mode, the first phase shifter circuit 5 is connected between the first sub line 31 and the second sub line 32, and thus the first phase shifter circuit 5 causes a change in a characteristic (for example, directivity) of the directional coupler 1 on occasions. Controlling the resistance value of the variable resistor 4a and the capacitance value of the variable capacitor 4b enables the change in the characteristic of the directional coupler 1 to be improved. The termination circuit 4 may have an invariable resistor instead of the variable resistor 4a. The termination circuit 4 may also have an invariable capacitor instead of the variable capacitor 4b.

In the second mode, the first phase shifter circuit 5 is connected between the first sub line 31 and the second sub line 32 that are used as the sub line 3 and is a circuit for controlling the phase of the sub line 3. The first phase shifter circuit 5 prevents a high frequency signal from leaking from the main line 2 to the sub line 3 by controlling the phase of the sub line 3 in the second mode. The first phase shifter circuit 5 is disposed on a signal path R1 between the first end 31a of the first sub line 31 and the second end 32b of the second sub line 32. In more detail, the first phase shifter circuit 5 has a first end 5a and a second end 5b. The first end 5a of the first phase shifter circuit 5 is connected to the selection terminal 6c of the first selector switch 6, and the second end 5b of the first phase shifter circuit 5 is connected to a terminal 7a of the second selector switch 7.

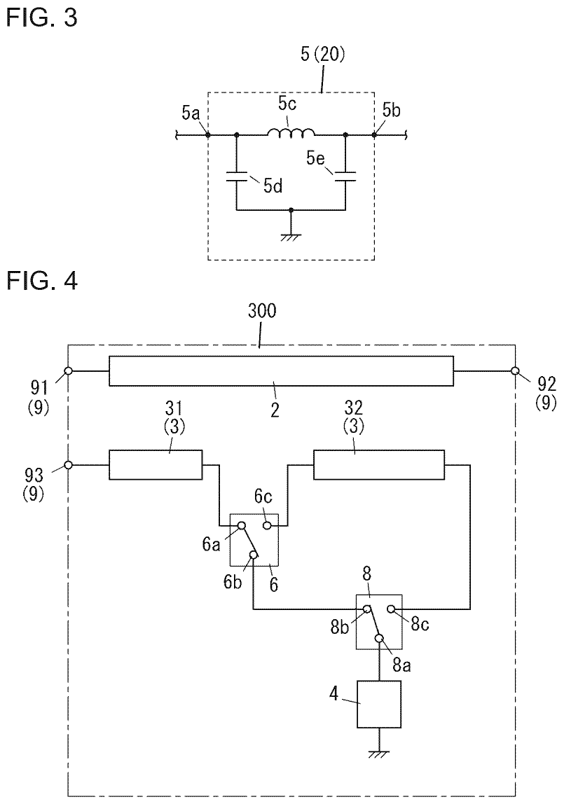

As illustrated in FIG. 3, the first phase shifter circuit 5 illustrated in FIG. 1 has, for example, an inductor 5c and two capacitors 5d and 5e. That is, the first phase shifter circuit 5 has a low pass filter composed of the inductor 5c and the two capacitors 5d and 5e. The inductor 5c is connected between the ends of the first phase shifter circuit 5 (the first end 5a and the second end 5b). The capacitor 5d is connected between the ground and a point of connection between the first end 5a of the first phase shifter circuit 5 and the inductor 5c. The capacitor 5e is connected between the ground and a point of connection between the second end 5b and the inductor 5c of the first phase shifter circuit 5.

The first selector switch 6 and the second selector switch 7 are each a switch for performing switching between the first mode in which only the first sub line 31 is used as the sub line 3 and the second mode in which both of the first sub line 31 and the second sub line 32 are used as the sub line 3. The first selector switch 6 and the second selector switch 7 are thus each a switch for performing switching between two lengths in the line length of the sub line 3.

The first selector switch 6 is disposed between the first sub line 31 and the first phase shifter circuit 5 and performs switching between connection and non-connection between the first sub line 31 and the first phase shifter circuit 5. The first selector switch 6 has the common terminal 6a and a plurality of (in the illustrated example, two) selection terminals 6b and 6c. The common terminal 6a is connected to the first end 31a of the first sub line 31. The selection terminal 6b is connected to a selection terminal 8b of the end switch 8. The selection terminal 6c is connected to the first end 5a of the first phase shifter circuit 5.

The first selector switch 6 connects the common terminal 6a and the selection terminal 6b in the first mode and connects the common terminal 6a and the selection terminal 6c in the second mode (that is, does not connect the common terminal 6a and the selection terminal 6b). The first sub line 31 and the termination circuit 4 are thereby connected in the first mode, and the first sub line 31 and the first phase shifter circuit 5 are connected in the second mode.

The second selector switch 7 is disposed between the first phase shifter circuit 5 and the second sub line 32 and performs switching between connection and non-connection between the first phase shifter circuit 5 and the second sub line 32. The second selector switch 7 has the two terminals 7a and 7b. The terminal 7a is connected to the second end 5b of the first phase shifter circuit 5, and the terminal 7b is connected to the second end 32b of the second sub line 32.

The second selector switch 7 does not connect the terminal 7a and the terminal 7b in the first mode and connects the terminal 7a and the terminal 7b in the second mode. The first phase shifter circuit 5 and the second sub line 32 are thereby not connected in the first mode, and the first phase shifter circuit 5 and the second sub line 32 are connected in the second mode.

The end switch 8 is a switch for performing switching of a connection target of the termination circuit 4 to one of the first sub line 31 and the second sub line 32. The end switch 8 has the common terminal 8a and the plurality of (in the illustrated example, two) selection terminals 8b and 8c. The common terminal 8a is connected to the termination circuit 4. The selection terminal 8b is connected to the selection terminal 6b of the first selector switch 6. The selection terminal 8c is connected to the first end 32a of the second sub line 32.

The end switch 8 connects the common terminal 8a and the selection terminal 8b in the first mode, and connects the common terminal 8a and the selection terminal 8c in the second mode. The first sub line 31 and the termination circuit 4 are thereby connected in the first mode, and the second sub line 32 and the termination circuit 4 are connected in the second mode.

The directional coupler 1 has the first mode and the second mode. The first mode is a mode in which a signal in a first frequency band among radio frequency signals that flow through the main line 2 is detected. The second mode is a mode in which a signal in a second frequency band among the radio frequency signals that flow through the main line 2 is detected. The first frequency band corresponds to, for example, a 1 GHz to 3 GHz frequency band (that is, a middle band (MB) and a high band (HB)), and the second frequency band corresponds to, for example, a frequency band lower than 1 GHz (that is, a low band (LB)). The first frequency band is thus a band with higher frequencies than those in the second frequency band. In the directional coupler 1, the first mode is a high band (HB) mode corresponding to the middle band (MB) and the HB and the second mode is a low band (LB) mode corresponding to the LB.

The directional coupler 1 uses the first sub line 31 as the sub line 3 in the first mode and uses the series circuit as the sub line 3 in the second mode, the series circuit having the first phase shifter circuit 5 connected between the first sub line 31 and the second sub line 32.

### (2) Operations

### (2.1) First Mode

As illustrated in FIG. 1, in the first mode, the directional coupler 1 connects the common terminal 8a and the selection terminal 8b of the end switch 8, connects the common terminal 6a and the selection terminal 6b of the first selector switch 6, and does not connect the terminal 7a and the terminal 7b of the second selector switch 7. The first sub line 31 is thereby connected between the third connection terminal 93 (that is, the coupling terminal) and the termination circuit 4. Of the first sub line 31 and the second sub line 32, only the first sub line 31 is thereby used as the sub line 3. The line length of the sub line 3 in this case is the same as the line length L1 of the first sub line 31.

In the first mode, the directional coupler 1 extracts, as a detection signal, part of the first signal in the first frequency band among the radio frequency signals that flow through the main line 2, from the sub line 3 (that is, the first sub line 31) and outputs the detection signal from the third connection terminal 93 to the external apparatus (for example, a detector).

### (2.2) Second Mode

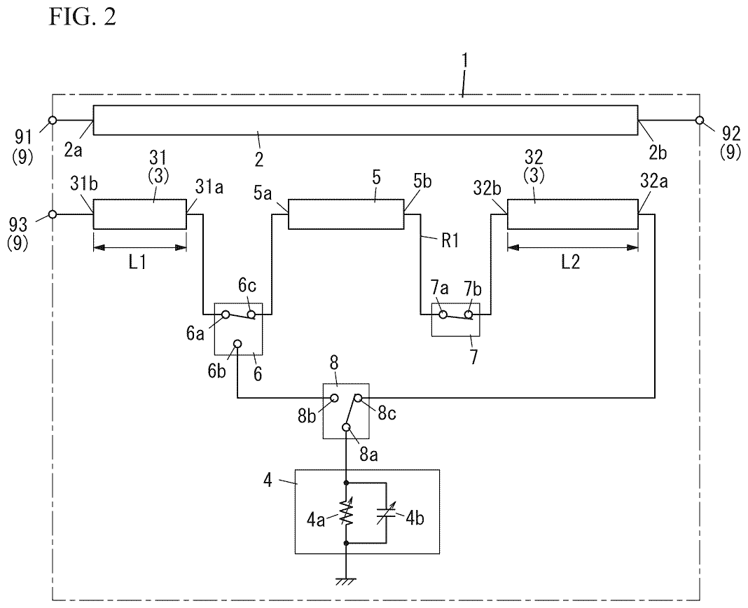

As illustrated in FIG. 2, in the second mode, the directional coupler 1 connects the common terminal 8a and the selection terminal 8c of the end switch 8, connects the common terminal 6a and the selection terminal 6c of the first selector switch 6, and connects the terminal 7a and the terminal 7b of the second selector switch 7. The first sub line 31 and the second sub line 32 are thereby connected in series to each other, and the first phase shifter circuit 5 is connected therebetween. The series circuit composed of the first sub line 31, the second sub line 32, and the first phase shifter circuit 5 is connected between the third connection terminal 93 (that is, the coupling terminal) and the termination circuit 4. The series circuit described above is thereby used as the sub line 3. The line length of the sub line 3 in this case is a sum of the line length L1 of the first sub line 31 and the line length L2 of the second sub line 32 (that is, L1+L2).

The line length of the sub line 3 (L1+L2) in the second mode is thereby longer than the line length L1 of the sub line 3 in the first mode. As the result, in the second mode, it is possible to extract, as the detection signal, the second signal in the second frequency band that is a frequency band lower than in the first mode from the main line 2 into the sub line 3. That is, in the second mode, the directional coupler 1 extracts, as a detection signal from the sub line 3, part of the first signal in the second frequency band among the radio frequency signals that flow through the main line 2 and outputs the detection signal from the third connection terminal 93 to the external apparatus (for example, the detector).

### (3) Insertion Loss of Detection-Excluded Signal in Directional Coupler

The following description assumes that the first frequency band is the higher frequency band (a frequency band corresponding to, for example, both of the middle band (MB) and the high band (HB)) and the second frequency band is the lower frequency band lower than the first frequency band (for example, the low band (LB)).

First, suppose a case where the first signal in the first frequency band is extracted as the detection signal from the sub line 3 and a case where the second signal in the second frequency band is extracted as the detection signal from the sub line 3, the first and second signals being extracted in a case where the first signal and the second signal simultaneously flow through the main line 2 in a directional coupler 300 in a comparative example.

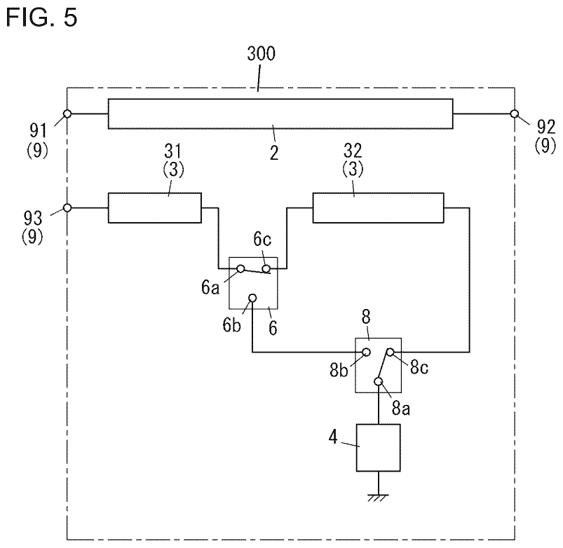

As illustrated in FIG. 4, the directional coupler 300 in the comparative example is configured in the same manner as in the directional coupler 1 in Embodiment 1 except that the first phase shifter circuit 5 and the second selector switch 7 are omitted and the second end of the second sub line 32 and the selection terminal 6c of the first selector switch 6 are connected. In the first mode (see FIG. 4), of the first sub line 31 and the second sub line 32, the directional coupler 300 uses only the first sub line 31 as the sub line 3, like the directional coupler 1. In contrast, in the second mode, the directional coupler 1 in Embodiment 1 and the directional coupler 300 in the comparative example use, as the sub line 3, both of the first sub line 31 and the second sub line 32. However, in the directional coupler 1 in Embodiment 1, the first phase shifter circuit 5 is connected between the first sub line 31 and the second sub line 32 that are used as the sub line 3 (see FIG. 2). In contrast, in the directional coupler 300 in the comparative example, the first phase shifter circuit 5 is not connected between the first sub line 31 and the second sub line 32 that are used as the sub line 3 (see FIG. 5).

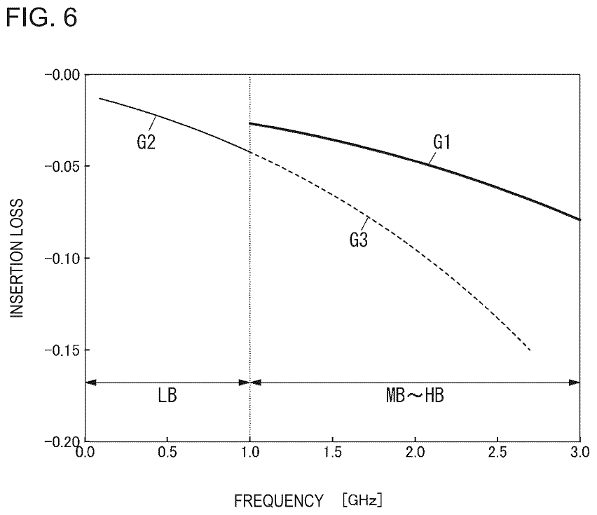

As illustrated in FIG. 4, in the directional coupler 300, in the case where the first signal (detection-targeted signal) in the higher frequency band is extracted as the detection signal from the sub line 3 (first mode), the sub line 3 is composed of only the first sub line 31 and is a relatively short sub line. In this case, in the relatively short sub line 3, only the first signal in the higher frequency band is extracted, and almost no second signal (detection-excluded signal) in the lower frequency band is extracted. Accordingly, in this case, almost no second signal leaks to the sub line 3, an insertion loss G1 occurs in the first signal flowing through the main line 2 (see FIG. 6), and an insertion loss does not occur in the second signal flowing through the main line 2.

In contrast, in the directional coupler 300, in the case where the second signal (detection-targeted signal) in the lower frequency band is extracted as the detection signal from the sub line 3 (second mode), the sub line 3 is formed as the series circuit of the first sub line 31 and the second sub line 32 and thus is a relatively long sub line. In this case, part of the second signal (detection-targeted signal) in the lower frequency band is extracted in the sub line 3, but part of the first signal (detection-excluded signal) in the higher frequency band is also extracted in such a manner as to leak thereto. Accordingly, in this case, at the same time as the detection-targeted signal (second signal) is extracted in the sub line 3, the detection-excluded signal (first signal) leaks thereto. As the result, at the same time as an insertion loss G2 occurs in the detection-targeted signal (second signal) flowing through the main line 2, an insertion loss G3 also occurs in the detection-excluded signal (first signal) flowing through the main line 2 (see FIG. 6). At this time, the greater the insertion loss G3 of the detection-excluded signal (first signal), the higher the frequency of the detection-excluded signal (first signal).

In the second mode, the insertion loss G3 of the first signal (detection-excluded signal) is greater than the insertion loss G1 of the first signal (detection-targeted signal) in the case where the first signal is extracted as the detection-targeted signal from the sub line 3 in the first mode (see FIG. 6). In FIG. 6, the graph G1 represents insertion losses of the detection-targeted signal (first signal) in the first mode. The graphs G2 and G3 represent insertion losses in the second mode, the graph G2 represents insertion losses of the detection-targeted signal (second signal), and the graph G3 represents insertion losses of the detection-excluded signal (first signal).

As described above, in the directional coupler 300 in the comparative example, when part of the second signal (detection-targeted signal) in the lower frequency band is extracted as the detection signal from the sub line 3 in the second mode, the first signal (detection-excluded signal) in the higher frequency band leaks from the main line 2 to the sub line 3, and the relatively great insertion loss G3 occurs in the second signal flowing through the main line 2.

In contrast, in the directional coupler 1 in Embodiment 1, in the case where the second signal (detection-targeted signal) in the lower frequency band is extracted as the detection signal from the sub line 3 in the second mode, the first phase shifter circuit 5 is connected between the first sub line 31 and the second sub line 32 in the sub line 3 (see FIG. 2). Controlling the phase of the sub line 3 with the first phase shifter circuit 5 causes the second signal in the lower frequency band to flow through the sub line 3 still readily and also causes the first signal in the higher frequency band to flow therethrough unreadily. As the result, the second signal in the lower frequency band is extracted in the sub line 3, but the first signal in the higher frequency band leaks thereto unreadily.

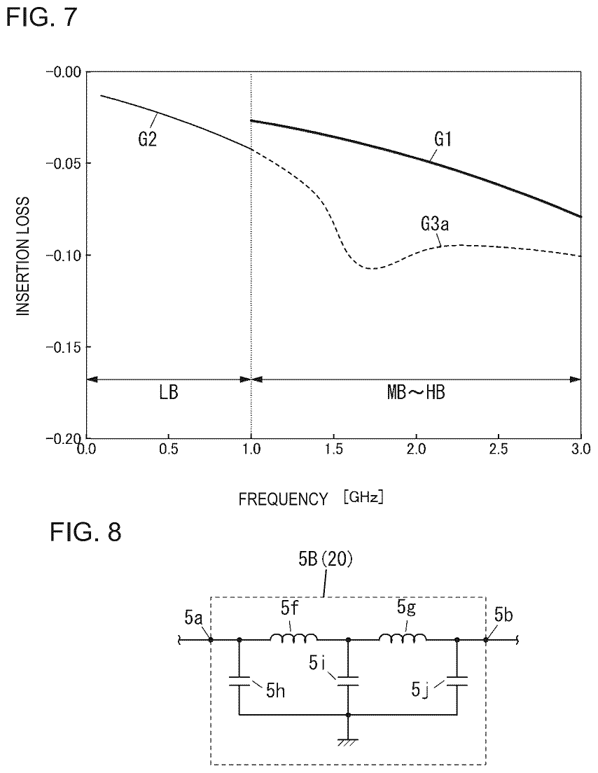

In the second mode, at the same time as the insertion loss G2 thereby occurs in the detection-targeted signal (second signal) flowing through the main line 2, the insertion loss G3a also occurs in the detection-excluded signal (first signal) flowing through the main line 2; however, the insertion loss G3a is prevented (see FIG. 7). In more detail, in the second mode, the insertion loss G3a of the detection-excluded signal (first signal) is constantly suppressed almost without necessarily being increased even if the frequency of the detection-excluded signal (first signal) is high (see FIG. 7). In addition, the insertion loss G3a is smaller than the insertion loss G3.

As described above, in the directional coupler 1 in Embodiment 1, in the case where part of the second signal (detection-targeted signal) in the lower frequency band is extracted as the detection signal from the sub line 3 in the second mode, the sub line in which the first phase shifter circuit 5 is connected between the first sub line 31 and the second sub line 32 is used as the sub line 3. Accordingly, the first signal (detection-excluded signal) in the higher frequency band is prevented from leaking from the main line 2 to the sub line 3 when the second signal (detection-targeted signal) is extracted as the detection signal from the sub line 3. As the result, the insertion loss G3a occurring in the first signal (detection-excluded signal) flowing through the main line 2 in the second mode is prevented.

In the communication apparatus using the directional coupler 1, it is thereby possible to prevent the insertion loss of the reception signal in the higher frequency band from causing the signal strength deterioration in a reception signal (detection-excluded signal) in the higher frequency band among reception signals in two frequency bands (the higher frequency band and the lower frequency band) that are simultaneously received by the communication apparatus with carrier aggregation (CA), when a reception signal (detection-targeted signal) in the lower frequency band is detected by the directional coupler 1.

### (4) Effects

The directional coupler 1 according to Embodiment 1 includes the main line 2, the first sub line 31 and the second sub line 32, the termination circuit 4, the first phase shifter circuit 5, the first selector switch 6, and the second selector switch 7. The termination circuit 4 terminates one of the first sub line 31 and the second sub line 32. The first phase shifter circuit 5 is disposed on the signal path R1 (first signal path) between the first sub line 31 and the second sub line 32. The first selector switch 6 performs switching between connection and non-connection between the first sub line 31 and the first phase shifter circuit 5. The second selector switch 7 performs switching between connection and non-connection between the first phase shifter circuit 5 and the second sub line 32.

According to the configuration, in the first mode in which part of the first signal of the first frequency band that flows through the main line 2 is extracted from the sub line 3, the first selector switch 6 causes non-connection between the first sub line 31 and the first phase shifter circuit 5, and the second selector switch 7 causes non-connection between the first phase shifter circuit 5 and the second sub line 32. It is thereby possible to use, as the sub line 3 described above, the sub line composed of one of the first sub line 31 and the second sub line 32 (the first sub line 31 in Embodiment 1).

In the second mode in which part of the second signal in the second frequency band (the frequency band lower than the first frequency band) flowing through the main line 2 is extracted from the sub line 3, the first selector switch 6 connects the first sub line 31 and the first phase shifter circuit 5, and the second selector switch 7 connects the first phase shifter circuit 5 and the second sub line 32. It is thereby possible to use, as the sub line 3 described above, the series circuit in which the first phase shifter circuit 5 is connected between the first sub line 31 and the second sub line 32.

As described above, in the sub line 3 used in the second mode, it is possible to connect the first phase shifter circuit 5 between the first sub line 31 and the second sub line 32. Accordingly, the first phase shifter circuit 5 enables a frequency characteristic to be changed for a signal flowing through the sub line 3 described above. In the second mode, it is thereby possible to prevent the loss (insertion loss G3a) from occurring in the first signal flowing through the main line 2 when part of the second signal (detection-targeted signal) of the first signal in the first frequency band and the second signal in the second frequency band that simultaneously flow through the main line 2 is extracted from the sub line 3, the loss being caused by leakage, to the sub line 3, of part of the first signal (detection-excluded signal) flowing through the main line 2. It is thus possible to prevent loss in the detection-excluded signal (first signal) flowing through the main line 2 simultaneously with the detection-targeted signal (second signal) from occurring when part of the detection-targeted signal flowing through the main line 2 is extracted from the sub line 3.

### (5) Modifications

Hereinafter, modifications of Embodiment 1 will be described. Embodiment 1 and any of the modifications may be implemented in combination. In the following description, the same components as those in Embodiment 1 are denoted by the same reference numerals, and description thereof is omitted on occasions.

### (5.1) Modification 1

Embodiment 1 assumes a case where a radio frequency signal flowing through the main line 2 from the first connection terminal 91 side thereof to the second connection terminal 92 side is detected in the sub line 3 (forward detection). However, in Embodiment 1, a radio frequency signal flowing through the main line 2 from the second connection terminal 92 side to the first connection terminal 91 side is detected in the sub line 3 (reverse detection). In this case, a connection target of the first sub line 31 and a connection target of the common terminal 8a of the end switch 8 are made switchable such that the connection targets of the second end 31b and the common terminal 8a are respectively the termination circuit 4 and the third connection terminal 93. It is thereby possible to perform both of the forward detection and the reverse detection. At this time, the first phase shifter circuit 5 enables impedance control between the case of the forward detection and the case of the reverse detection.

### (5.2) Modification 2

The first phase shifter circuit 5 in Embodiment 1 is a third-order phase shifter circuit (see FIG. 3), but a first phase shifter circuit 5B in Modification 2 is a phase shifter circuit with a degree other than a third order as illustrated in FIG. 8 (fifth order in the example in FIG. 8). The term “N-th order (N=1, 2, 3, . . . ) phase shifter circuit” denotes that the phase shifter circuit is composed of N circuit components. The first phase shifter circuit 5B illustrated in FIG. 8 has two inductors 5f and 5g and capacitors 5h, 5i, and 5j. The two inductors 5f and 5g are connected in series to each other and between the ends (the first end 5a and the second end 5b) of the first phase shifter circuit 5. The capacitor 5h is connected between the ground and a point of connection between the first end 5a of the first phase shifter circuit 5B and the inductor 5f. The capacitor 5i is connected between the ground and a point of connection between the inductor 5f and the inductor 5g. The capacitor 5j is connected between the ground and a point of connection between the second end 5b of the first phase shifter circuit 5B and the inductor 5g. FIG. 3 illustrates a circuit in which the inductor 5c and the capacitors 5d and 5e are connected in a so-called π form; however, the circuit may be configured as a T-type circuit in which the two inductors are connected in series on a path between the first end 5a and the second end 5b and an inductor is disposed between the connection point of the inductors and the ground.

### (5.3) Modification 3

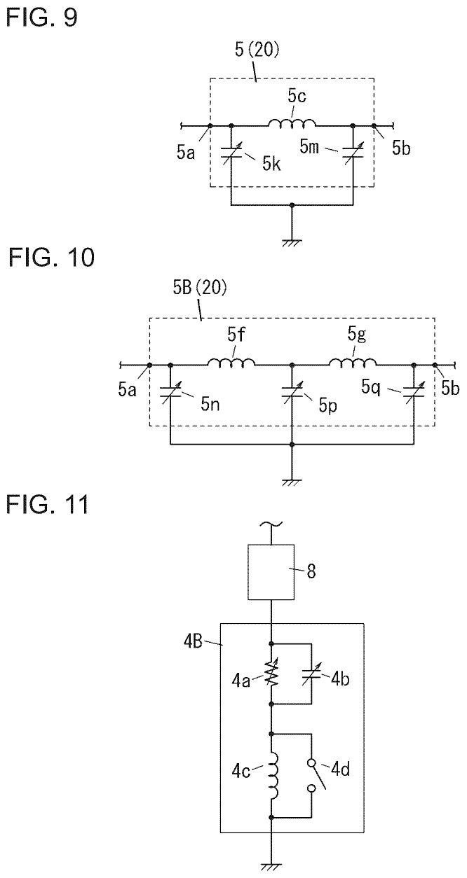

The first phase shifter circuit 5 in Embodiment 1 is composed of the circuit components (the inductor 5c and the capacitors 5d and 5e) with fixed characteristic values (see FIG. 3). A characteristic value of a circuit component is a value that specifies a characteristic regarding a function of the circuit component. The characteristic value is a resistance value if the circuit component is a variable resistor, is a capacitance value if the circuit component is a capacitor, and is inductance if the circuit component is an inductor. In contrast, as illustrated in FIG. 9, the first phase shifter circuit 5 in Modification 3 is composed of circuit components (variable capacitors 5k and 5m) with variable characteristic values. The first phase shifter circuit 5 in Modification 3 is thus a circuit in which the circuit components (the inductor 5c and the capacitors 5d and 5e) of the first phase shifter circuit 5 in Embodiment 1 are replaced with the circuit components (the variable capacitors 5k and 5m) with variable characteristic values.

According to Modification 3, it is possible to control the characteristic values of the circuit components constituting the first phase shifter circuit 5. This enables fine adjustment of a frequency characteristic of the degree of coupling between the sub line 3 and the main line 2 that are used in the second mode. It is thereby possible to further prevent the occurrence of loss in the first signal flowing through the main line 2 when part of the second signal of the first signal and the second signal that simultaneously flow through the main line 2 is extracted from the sub line 3. In addition, even if the frequency characteristic of the degree of coupling described above is changed due to a change in impedance or the like of the sub line 3 used in the second mode, it is possible to easily control the frequency characteristic of the degree of coupling described above.

Note that the circuit components (the capacitors 5h, 5i, and 5j (see FIG. 8)) of the first phase shifter circuit 5B in Modification 2 may each be replaced with a corresponding one of the circuit components (variable capacitors 5n, 5p, and 5q) with the variable characteristic values, as illustrated in FIG. 10.

### (5.4) Modification 4

As illustrated in FIG. 11, a termination circuit 4B in Modification 4 further includes an inductor 4c and a switch 4d in the termination circuit 4 in Embodiment 1. The inductor 4c is connected in series to one of the variable resistor 4a and the variable capacitor 4b connected in parallel to each other. In Modification 4, the termination circuit 4 includes both of the variable resistor 4a and the variable capacitor 4b; however, if the termination circuit 4 includes at least one of the variable resistor 4a or the variable capacitor 4b, the inductor 4c is connected in series to the at least one.

In more detail, the inductor 4c is connected in series between the ground and one of the variable resistor 4a and the variable capacitor 4b. The switch 4d is connected in parallel to the inductor 4c. The inductor 4c is a circuit component for controlling the impedance of the termination circuit 4. The switch 4d is a switch for performing switching between connection (a short circuit) and non-connection (an open circuit) between the ends of the inductor 4c. Performing switching between the connection and non-connection of the switch 4d makes a characteristic of the directional coupler 1 (for example, directivity) controllable.

In more detail, in Embodiment 1, in the second mode, the first phase shifter circuit 5 is connected between the first sub line 31 and the second sub line 32, and thus the first phase shifter circuit 5 causes a change in a characteristic of the directional coupler 1 (for example, directivity) on occasions. Connection or non-connection of the switch 4d enables the change in the characteristic of the directional coupler 1 to be improved. For example, since the first phase shifter circuit 5 is not connected to the sub line 3 when the directional coupler 1 is in the first mode, the switch 4d is connected to cause the inductor 4c to be short circuited. In contrast, since the first phase shifter circuit 5 is connected to the sub line 3 when the directional coupler 1 is in the second mode, the inductor 4c is enabled by causing the switch 4d not to be connected to improve the change in the characteristic of the directional coupler 1 due to the first phase shifter circuit 5.

### (5.5) Modification 5

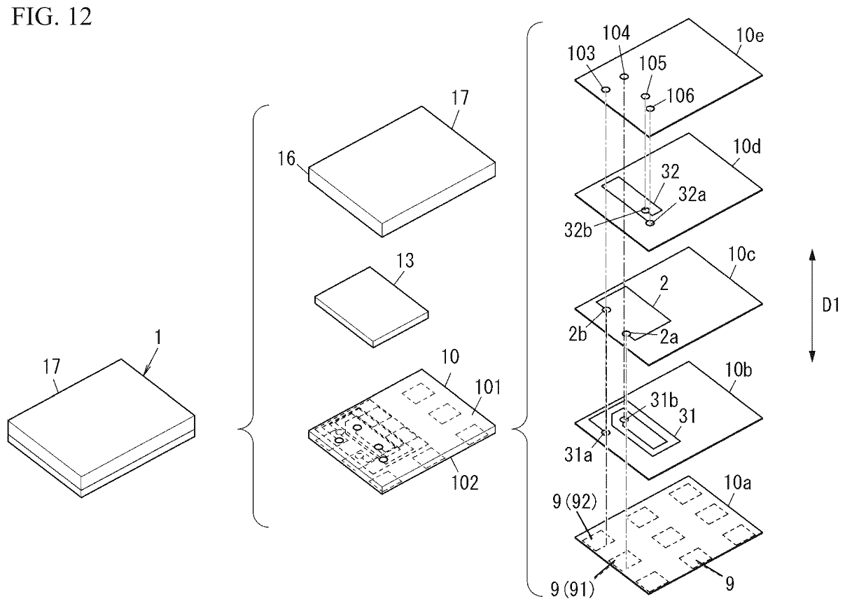

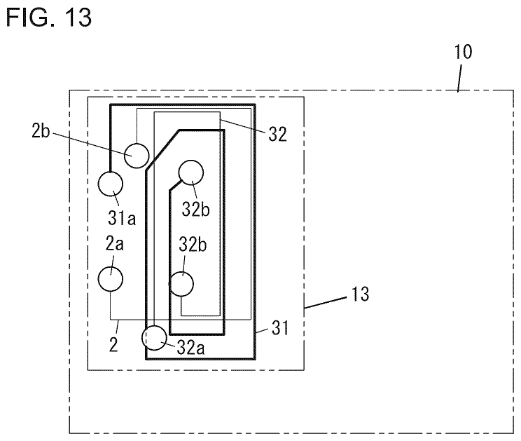

An example of the structure of the directional coupler 1 will be described with reference to FIGS. 12 and 13. As illustrated in FIG. 12, the directional coupler 1 includes a mounting substrate 10, an integrated circuit (IC) chip 13, a first resin layer 16, and a metal electrode layer 17.

The IC chip 13 is a semiconductor IC including the first selector switch 6, the second selector switch 7, the end switch 8, and the control circuit. The control circuit controls the respective connection targets of the terminals 6a, 7a, and 8a of the first selector switch 6, the second selector switch 7, and the end switch 8 in accordance with a control signal from the outside. The IC chip 13 includes the first phase shifter circuit 5 in addition to the first selector switch 6, the second selector switch 7, and the end switch 8. The IC chip 13 is thus integrated with the first selector switch 6, the second selector switch 7, the end switch 8, and the first phase shifter circuit 5.

The mounting substrate 10 is a multilayer substrate having, for example, a plurality of (in the illustrated example, five) layers 10a to 10e. The plurality of layers 10a to 10e include the first layer 10a, the second layer 10b, the third layer 10c, the fourth layer 10d, and the fifth layer 10e.

A plurality of (in the illustrated example, nine) connection terminals 9 are arranged on a surface (back surface) of the first layer 10a. A conductor pattern part forming the first sub line 31 is formed in a surface (front surface) of the second layer 10b. A conductor pattern part forming the main line 2 is formed in a surface (front surface) in the third layer 10c. A conductor pattern part forming the second sub line 32 is formed in a surface (front surface) of the fourth layer 10d. A plurality of (in the illustrated example, four) terminals 103 to 106 are formed on the fifth layer 10e.

The terminal 103 corresponds to the first end 31a of the first sub line 31 and is connected to the first end 31a of the first sub line 31 with the via conductors (not illustrated) interposed therebetween. The terminal 104 corresponds to the second end 31b of the first sub line 31 and is connected to the second end 31b of the first sub line 31 with the via conductors (not illustrated) interposed therebetween. The terminal 105 corresponds to the second end 32b of the second sub line 32 and is connected to the second end 32b of the second sub line 32 with the via conductors (not illustrated) interposed therebetween. The terminal 106 corresponds to the first end 32a of the second sub line 32 and is connected to the first end 32a of the second sub line 32 with the via conductors (not illustrated) interposed therebetween. The first end 2a of the main line 2 is connected to the connection terminal 91 (9) with the via conductors (not illustrated) interposed therebetween. The second end 2b of the main line 2 is connected to the connection terminal 92 (9) with the via conductors (not illustrated) interposed therebetween.

In the mounting substrate 10, the first layer 10a, the second layer 10b, the third layer 10c, the fourth layer 10d, and the fifth layer 10e are stacked in this order from the lower side. The main line 2, the first sub line 31, and the second sub line 32 are thereby provided inside the mounting substrate (the multilayer substrate) 10. The IC chip 13 is disposed on a first main surface 101 (front surface) of the fifth layer 10e of the mounting substrate 10. The first resin layer 16 is disposed on the first main surface 101 of the mounting substrate 10 in such a manner as to cover the IC chip 13. The metal electrode layer 17 is disposed on the first main surface 101 side of the mounting substrate 10 in such a manner as to cover the first resin layer 16.

As illustrated in FIG. 13, in the directional coupler 1, in plan view in a thickness direction D1 of the mounting substrate 10 (see FIG. 12), the main line 2, the first sub line 31, and the second sub line 32 overlap with the IC chip 13. It is thereby possible to reduce a connection distance between the IC chip 13 and the directional coupler 1, and as the result of this, it is possible to prevent an optional inductor from being generated on wiring connecting the IC chip 13 and the directional coupler 1. In plan view in the thickness direction D1 of the mounting substrate 10, the IC chip 13 may overlap with one or two of the main line 2, the first sub line 31, and the second sub line 32. The IC chip 13 may thus overlap with at least one of the main line 2, the first sub line 31, of the second sub line 32 in plan view in the thickness direction D1 of the mounting substrate 10.

In addition, since the first phase shifter circuit 5 is integrated with the IC chip 13, it is possible to dispose the first phase shifter circuit 5 physically away from the main line 2 disposed inside the mounting substrate 10. This enables avoidance of optional coupling between the first phase shifter circuit 5 and the main line 2. In Modification 5, since the IC chip 13 is integrated with the first phase shifter circuit 5, the first selector switch 6, and the second selector switch 7, the first phase shifter circuit 5 is disposed in proximity to the first selector switch 6 and the second selector switch 7. It is thus possible to reduce a connection distance between the first phase shifter circuit 5 and each of the first selector switch 6 and the second selector switch 7. This enables the phase of the sub line 3 in the second mode to be controlled with high accuracy.

### Embodiment 2

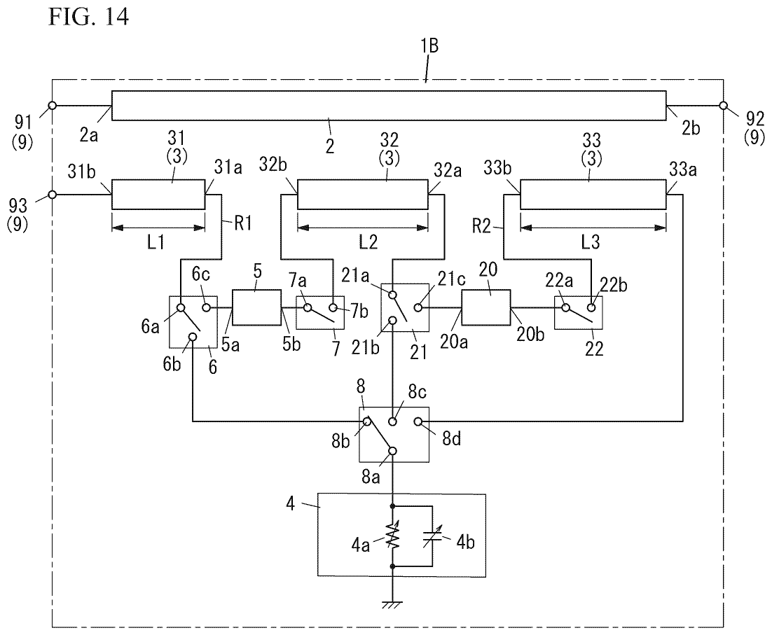

A directional coupler 1B according to Embodiment 2 will be described with reference to FIG. 14. For the directional coupler 1B according to Embodiment 2, the same components as those of the directional coupler 1 according to Embodiment 1 are denoted by the same reference numerals, and description thereof is omitted on occasions.

The directional coupler 1B is different from the directional coupler 1 according to Embodiment 1 in a point that a third sub line 33, a second phase shifter circuit 20, a third selector switch 21, and a fourth selector switch 22 are further included in the directional coupler 1 according to Embodiment 1. That is, the length of the sub line 3 is changeable between the two lengths in Embodiment 1, but the length of the sub line 3 is changeable between three lengths in Embodiment 2.

### (1) Configuration

The directional coupler 1B includes the main line 2, the first sub line 31, the second sub line 32, the third sub line 33, the first phase shifter circuit 5, the second phase shifter circuit 20, the first to fourth selector switches 6, 7, 21, and 22, the end switch 8, and the termination circuit 4.

The main line 2, the first sub line 31, the second sub line 32, the first phase shifter circuit 5, the first selector switch 6, the second selector switch 7, and the termination circuit 4 in Embodiment 2 are respectively configured in the same manner as in the main line 2, the first sub line 31, the second sub line 32, the first phase shifter circuit 5, the first selector switch 6, the second selector switch 7, and the termination circuit 4 in Embodiment 1.

The first end 32a of the second sub line 32 in Embodiment 2 is connected to a common terminal 21a of the third selector switch 21.

The third sub line 33 has a first end 33a and a second end 33b that are the ends, in the longitudinal direction, of the third sub line 33. The first end 33a of the third sub line 33 is connected to a selection terminal 8d of the end switch 8. The second end 33b of the third sub line 33 is connected to a terminal 22b of the fourth selector switch 22.

The first sub line 31, the second sub line 32, and the third sub line 33 are disposed on the same side of, for example, the main line 2 and arranged in the longitudinal direction of the main line 2. The lengths L1 and L2 of the respective first and second sub lines 31 and 32 and a length L3 of the third sub line 33 are different from each other. In Embodiment 2, the length L1 of the first sub line 31 is the shortest, the length L3 of the third sub line 33 is the longest, and the length L2 of the second sub line 32 is longer than the length L1 of the first sub line 31 and shorter than the length L3 of the third sub line 33. The lengths L1 to L3 of the first to third sub lines 31 to 33 may be the same as each other.

The second phase shifter circuit 20 is connected between the second sub line 32 and the third sub line 33 of the first to third sub lines used as the sub line 3 in a third mode and is a circuit for controlling the phase of the sub line 3. The second phase shifter circuit 20 causes a high frequency signal to flow through the sub line 3 unreadily by controlling the phase of the sub line 3 in the third mode. The second phase shifter circuit 20 is disposed on a signal path R2 between the first end 32a of the second sub line 32 and the second end 33b of the third sub line 33. In more detail, the second phase shifter circuit 20 has a first end 20a and a second end 20b. The first end 20a of the second phase shifter circuit 20 is connected to a selection terminal 21c of the third selector switch 21, and the second end 20b of the second phase shifter circuit 20 is connected to a terminal 22a of the fourth selector switch 22.

The second phase shifter circuit 20 includes, for example, a low pass filter. The second phase shifter circuit 20 has characteristics different from those of the first phase shifter circuit 5. That is, the low pass filter of the second phase shifter circuit 20 has characteristics different from those of the low pass filter of the first phase shifter circuit 5. The second phase shifter circuit 20 may have the same characteristics as those of the first phase shifter circuit 5. The low pass filter of the second phase shifter circuit 20 may thus have the same characteristics as those of the low pass filter of the first phase shifter circuit 5. The first phase shifter circuit 5 may have the same circuit configuration as that of the second phase shifter circuit 20 and may also have a circuit configuration different from that of the second phase shifter circuit 20. The circuit components included in the second phase shifter circuit 20 may be circuit components with fixed characteristic values and may also be circuit components with variable characteristic values. The second phase shifter circuit 20 may have the circuit configuration described with reference to, for example, FIGS. 3, 8, and 9.

The end switch 8 in Embodiment 2 is configured in the same manner as in the end switch 8 in Embodiment 1 except that the end switch 8 in Embodiment 2 is different in the following points. The selection terminal 8d is further included in the end switch 8 in Embodiment 1, and the connection target of the common terminal 8a is connected selectively to one of the three selection terminals 8b to 8d. The end switch 8 in Embodiment 2 has the common terminal 8a and the plurality of (in the illustrated example, three) selection terminals 8b, 8c, and 8d. The common terminal 8a is connected to the termination circuit 4. The selection terminal 8b is connected to the selection terminal 6b of the first selector switch 6. The selection terminal 8c is connected to a selection terminal 21b of the third selector switch 21. The selection terminal 8d is connected to the first end 33a of the third sub line 33.

The third selector switch 21 is disposed between the second sub line 32 and the second phase shifter circuit 20 and performs switching between connection and non-connection between the second sub line 32 and the second phase shifter circuit 20. The third selector switch 21 has the common terminal 21a and the plurality of (in the illustrated example, two) selection terminals 21b and 21b. The common terminal 21a is connected to the first end 32a of the second sub line 32. The selection terminal 21b is connected to the selection terminal 8c of the end switch 8. The selection terminal 21c is connected to the first end 20a of the second phase shifter circuit 20.

The fourth selector switch 22 is disposed between the second phase shifter circuit 20 and the third sub line 33 and performs switching between connection and non-connection between the second phase shifter circuit 20 and the third sub line 33. The fourth selector switch 22 has the two terminals 22a and 22b. The terminal 22a is connected to the second end 20b of the second phase shifter circuit 20. The terminal 22b is connected to the second end 33b of the third sub line 33.

The directional coupler 1B has the first mode, the second mode, and the third mode. The first mode is a mode in which the first signal in the first frequency band among the radio frequency signals flowing through the main line 2 is detected. The second mode is a mode in which the second signal in the second frequency band among the radio frequency signals flowing through the main line 2 is detected. The third mode is a mode in which the third signal in the third frequency band among the radio frequency signals flowing through the main line 2 is detected. The first frequency band is a band with higher frequencies than those in the second frequency band. The second frequency band is a band with higher frequencies than those in the third frequency band. In the directional coupler 1B according to in Embodiment 3, for example, the first mode is the high band (HB) mode, the second mode is a mid-band (MB) mode, and the third mode is the low band (LB) mode.

### (2) Operations

### (2.1) First Mode

In the first mode, the directional coupler 1B connects the common terminal 8a and the selection terminal 8b of the end switch 8 and connects the common terminal 6a and the selection terminal 6b of the first selector switch 6. At this time, the terminal 7a is not connected to the terminal 7b of the second selector switch 7, the common terminal 21a of the third selector switch 21 is not connected to any of the plurality of selection terminals 21b and 21b, and the terminal 22a is not connected to the terminal 22b of the fourth selector switch 22. The first sub line 31 and the termination circuit 4 are thereby connected, and the first sub line 31 is used as the sub line 3. Part of the first signal (detection-targeted signal) in the first frequency band among the radio frequency signals flowing through the main line 2 from the sub line 3 (that is, the first sub line 31) is extracted as a detection signal from the sub line 3.

### (2.2) Second Mode

In the second mode, the directional coupler 1B connects the common terminal 8a and the selection terminal 8c of the end switch 8, connects the common terminal 6a of the first selector switch 6 and the selection terminal 6c, connects the terminal 7a and the terminal 7b of the second selector switch 7, and connects the common terminal 21a of the third selector switch 21 to the selection terminal 21b thereof. At this time, the terminal 22a and the terminal 22b of the fourth selector switch 22 are not connected. The first sub line 31, the first phase shifter circuit 5, and the second sub line 32 are thereby connected in series in this order to form a series circuit, and the series circuit is connected to the termination circuit 4. The series circuit described above is thus used as the sub line 3. Part of the second signal (detection-targeted signal) in the second frequency band among the radio frequency signals flowing through the main line 2 is extracted as a detection signal from the sub line 3. At this time, the first phase shifter circuit 5 in the sub line 3 prevents the first signal (detection-excluded signal) in the first frequency band that flows through the main line 2 from leaking to the sub line 3, and insertion loss of the first signal in the first frequency band that flows through the main line 2 is prevented.

### (2.3) Third Mode

In the third mode, the directional coupler 1B connects the common terminal 8a and the selection terminal 8d of the end switch 8, connects the common terminal 6a and the selection terminal 6c of the first selector switch 6, connects the terminal 7a and the terminal 7b of the second selector switch 7, connects the common terminal 21a and the selection terminal 21c of the third selector switch 21, and connects the terminal 22a and the terminal 22b of the fourth selector switch 22. The first sub line 31, the first phase shifter circuit 5, the second sub line 32, the second phase shifter circuit 20, and the third sub line 33 are thereby connected in series in this order to form a series circuit, and the series circuit is connected to the termination circuit 4. The series circuit described above is thus used as the sub line 3. Part of the third signal (detection-targeted signal) in the third frequency band among the radio frequency signals flowing through the main line 2 is extracted as a detection signal from the sub line 3. At this time, the first phase shifter circuit 5 and the second phase shifter circuit 20 in the sub line 3 prevent the first signal (detection-excluded signal) in the first frequency band and the second signal (detection-excluded signal) in the second frequency band that flow through the main line 2 from leaking to the sub line 3. As the result, insertion loss of each of the first signal in the first frequency band and the second signal in the second frequency band that flow through the main line 2 is prevented.

### Embodiment 3

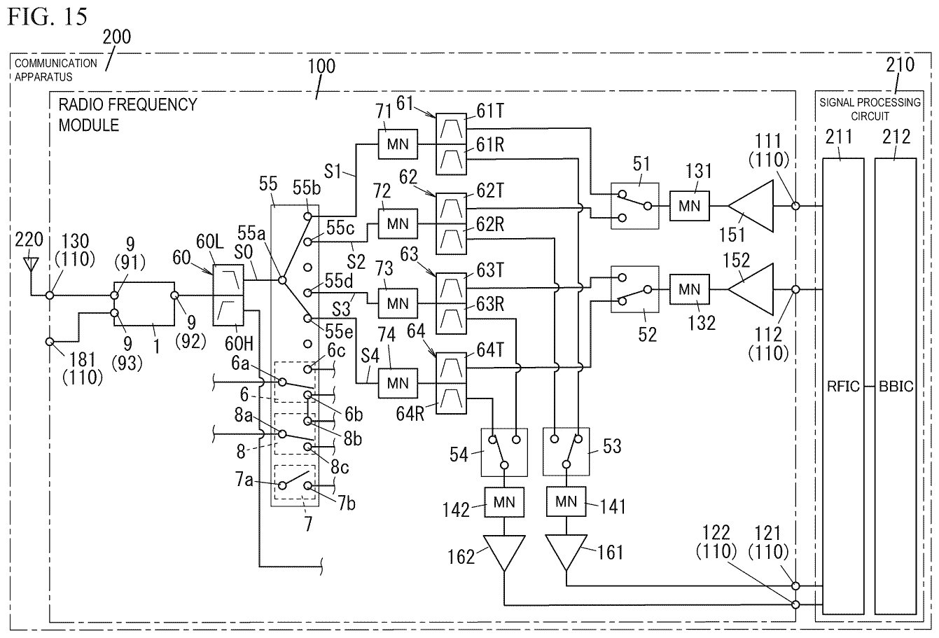

A radio frequency module 100 and a communication apparatus 200 according to Embodiment 3 will be described with reference to FIG. 15. The radio frequency module 100 according to Embodiment 3 is an example of a radio frequency module including the directional coupler 1 in Embodiment 1. The communication apparatus 200 according to Embodiment 3 is an example of the communication apparatus 200 including the radio frequency module 100.

### (1) Configuration of Communication Apparatus

The communication apparatus 200 is, for example, a mobile terminal (for example, a smartphone) or a wearable terminal (for example, a smart watch). The communication apparatus 200 includes the radio frequency module 100, a signal processing circuit 210, and an antenna 220.

The radio frequency module 100 is configured to extract a reception signal in a predetermined frequency band from reception signals received by the antenna 220, amplify the reception signal, and output the reception signal to the signal processing circuit 210. The radio frequency module 100 is also configured to amplify a transmission signal output from the signal processing circuit 210, convert the transmission signal in a predetermined frequency band, and output the transmission signal from the antenna 220.

The signal processing circuit 210 is connected to the radio frequency module 100 and is configured to perform signal processing of a radio frequency signal. In more detail, the signal processing circuit 210 performs signal processing of a reception signal output from the radio frequency module 100 and also performs signal processing of a transmission signal to be output to the radio frequency module 100. The signal processing circuit 210 includes a RF signal processing circuit 211 and a baseband signal processing circuit 212.

The RF signal processing circuit 211 is, for example, a radio frequency integrated circuit (RFIC). The RF signal processing circuit 211 is configured to perform signal processing such as downconverting of the reception signal output from the radio frequency module 100 and output the reception signal to the baseband signal processing circuit 212. The RF signal processing circuit 211 is also configured to perform signal processing such as upconverting of a transmission signal output from the baseband signal processing circuit 212 and output the transmission signal to the radio frequency module 100. The baseband signal processing circuit 212 is, for example, a baseband integrated circuit (BBIC). The baseband signal processing circuit 212 is configured to output a reception signal output from the RF signal processing circuit 211 to the outside. The baseband signal processing circuit 212 is configured to generate a transmission signal from a baseband signal (for example, an audio signal or an image signal) input from the outside and output the generated transmission signal to the RF signal processing circuit 211.

### (2) Configuration of Radio Frequency Module

The radio frequency module 100 includes a plurality of external connection terminals 110, power amplifiers 151 and 152, low noise amplifiers 161 and 162, transmission filters 61T to 64T, reception filters 61R to 64R, output matching circuits 131 and 132, matching circuits 141 and 142, matching circuits 71 to 74, switches 51 to 55, a diplexer 60, and the directional coupler 1 (coupler).

The plurality of external connection terminals 110 include an antenna terminal 130, two signal input terminals 111 and 112, two signal output terminals 121 and 122, and a coupler output terminal 181. The antenna terminal 130 is a terminal to which the antenna 220 is connected. The two signal input terminals 111 and 112 are each a terminal to which a transmission signal from the signal processing circuit 210 is input and are connected to an output part of the signal processing circuit 210. The two signal output terminals 121 and 122 are each a terminal from which a transmission signal from the radio frequency module 100 is output to the signal processing circuit 210 and are connected to an input part of the signal processing circuit 210. The coupler output terminal 181 is a terminal from which a detection signal extracted by the directional coupler 1 is output to the outside (for example, the signal processing circuit 210).

The power amplifiers 151 and 152 each has an input part and an output part. The input parts of the power amplifiers 151 and 152 are respectively connected to the signal input terminals 111 and 112, and the output parts of the power amplifiers 151 and 152 are respectively connected to common terminals of the switches 51 and 52 with the output matching circuits 131 and 132 interposed therebetween. The power amplifiers 151 and 152 respectively amplify transmission signals input from the signal input terminals 111 and 112 and output the amplified transmission signals to the common terminals of the switches 51 and 52 with the output matching circuits 131 and 132 interposed therebetween.

The switch 51 has the common terminal and two selection terminals (a first selection terminal and a second selection terminal). The common terminal of the switch 51 is connected to the power amplifier 151 with the output matching circuit 131 interposed therebetween. The two selection terminals of the switch 51 are respectively connected to input parts of the transmission filters 61T and 62T. The switch 51 selectively outputs, to one of the transmission filters 61T and 62T, an output signal from the power amplifier 151. The switch 52 has the common terminal and two selection terminals (a first selection terminal and a second selection terminal). The common terminal of the switch 52 is connected to the power amplifier 152 with the output matching circuit 132 interposed therebetween. The two selection terminals of the switch 52 are respectively connected to input parts of the transmission filters 63T and 64T. The switch 52 selectively outputs, to one of the transmission filters 63T and 64T, an output signal from the power amplifier 152.

The transmission filter 61T has the input part and an output part. The input part of the transmission filter 61T is connected to the first selection terminal of the switch 51, and the output part of the transmission filter 61T is connected to the switch 55 with the matching circuit 71 interposed therebetween. The transmission filter 61T allows, to pass, a transmission signal in a transmission band as the first communication band among transmission signals amplified by the power amplifier 151. The transmission filter 62T has the input part and an output part. The input part of the transmission filter 62T is connected to the second selection terminal of the switch 51, and the output part of the transmission filter 62T is connected to the switch 55 with the matching circuit 72 interposed therebetween. The transmission filter 62T allows, to pass, a transmission signal in a transmission band as the second communication band among the transmission signals amplified by the power amplifier 151.

The transmission filter 63T has the input part and an output part. The input part of the transmission filter 63T is connected to the first selection terminal of the switch 52, and the output part of the transmission filter 63T is connected to the switch 55 with the matching circuit 73 interposed therebetween. The transmission filter 63T allows, to pass, a transmission signal in a transmission band as the third communication band among transmission signals amplified by the power amplifier 152. The transmission filter 64T has the input part and an output part. The input part of the transmission filter 64T is connected to the second selection terminal of the switch 52, and the output part of the transmission filter 64T is connected to the switch 55 with the matching circuit 74 interposed therebetween. The transmission filter 64T allows, to pass, a transmission signal in a transmission band as the fourth communication band among the transmission signals amplified by the power amplifier 152.

The low noise amplifiers 161 and 162 each has an input part and an output part. The input parts of the low noise amplifiers 161 and 162 are respectively connected to common terminals of the switches 53 and 54 with the matching circuits 141 and 142 interposed therebetween. The output parts of the low noise amplifiers 161 and 162 are respectively connected to the signal output terminals 121 and 122. The low noise amplifiers 161 and 162 respectively amplify reception signals output from the switches 53 and 54 and output the amplified signals to the signal output terminals 121 and 122.

The switch 53 has the common terminal and two selection terminals (a first selection terminal and a second selection terminal). The common terminal of the switch 53 is connected to the low noise amplifier 161 with the matching circuit 141 interposed therebetween, and the two selection terminals of the switch 53 are respectively connected to output parts of the reception filters 61R and 62R. The switch 53 selectively outputs, to the low noise amplifier 161, a reception signal from one of the reception filters 61R and 62R. The switch 54 has the common terminal and two selection terminals (a first selection terminal and a second selection terminal). The common terminal of the switch 54 is connected to the low noise amplifier 162 with the matching circuit 142 interposed therebetween, and the two selection terminals of the switch 54 are respectively connected to output parts of the reception filters 63R and 64R. The switch 54 selectively outputs, to the low noise amplifier 162, a reception signal from one of the reception filters 63R and 64R.

The reception filter 61R has an input part and the output part. The input part of the reception filter 61R is connected to a selection terminal of the switch 55 with the matching circuit 71 interposed therebetween, and the output part of the reception filter 61R is connected to the first selection terminal of the switch 53. The reception filter 61R allows, to pass, a reception signal in a reception band as the first communication band among transmission signals output from the switch 55. The reception filter 62R has an input part and the output part. The input part of the reception filter 62R is connected to a selection terminal of the switch 55 with the matching circuit 72 interposed therebetween, and the output part of the reception filter 62R is connected to the second selection terminal of the switch 53. The reception filter 62R allows, to pass, a reception signal in a reception band as the second communication band among the transmission signals output from the switch 55.

The reception filter 63R has an input part and the output part. The input part of the reception filter 63R is connected to a selection terminal of the switch 55 with the matching circuit 73 interposed therebetween, and the output part of the reception filter 63R is connected to the first selection terminal of the switch 54. The reception filter 63R allows, to pass, a reception signal in a reception band as the third communication band among reception signals output from the switch 55. The reception filter 64R has an input part and the output part. The input part of the reception filter 64R is connected to a selection terminal of the switch 55 with the matching circuit 74 interposed therebetween, and the output part of the reception filter 64R is connected to the second selection terminal of the switch 54. The reception filter 64R allows, to pass, a reception signal in a reception band as the fourth communication band among the reception signals output from the switch 55.

The output matching circuit 131 is connected between the output part of the power amplifier 151 and the common terminal of the switch 51 and performs impedance matching between the power amplifier 151 and each of the transmission filters 61T and 62T. The output matching circuit 132 is connected between the output part of the power amplifier 152 and the common terminal of the switch 52 and performs impedance matching between the power amplifier 152 and each of the transmission filters 63T and 64T. The matching circuit 141 is connected between the input part of the low noise amplifier 161 and the common terminal of the switch 53 and performs impedance matching between the low noise amplifier 161 and each of the reception filters 61R and 62R. The matching circuit 142 is connected between the input part of the low noise amplifier 162 and the common terminal of the switch 54 and performs impedance matching between the low noise amplifier 162 and each of the reception filters 63R and 64R.

The matching circuit 71 is connected between a selection terminal 55b (described later) of the switch 55 and each of the output part of the transmission filter 61T and the input part of the reception filter 61R and performs impedance matching between the switch 55 and each of the transmission filter 61T and the reception filter 61R. The matching circuit 72 is connected between a selection terminal 55c (described later) of the switch 55 and each of the output part of the transmission filter 62T and the input part of the reception filter 62R and performs impedance matching between the switch 55 and each of the transmission filter 62T and the reception filter 62R. The matching circuit 73 is connected between a selection terminal 55d (described later) of the switch 55 and each of the output part of the transmission filter 63T and the input part of the reception filter 63R and performs impedance matching between the switch 55 and each of the transmission filter 63T and the reception filter 63R. The matching circuit 74 is connected between a selection terminal 55e (described later) of the switch 55 and each of the output part of the transmission filter 64T and the input part of the reception filter 64R and performs impedance matching between the switch 55 and each of the transmission filter 64T and the reception filter 64R.

The diplexer 60 has a first filter 60L and a second filter 60H. The first filter 60L is a filter using a passband in a frequency range including the first to fourth frequency bands described above. The second filter 60H is a filter using a passband in a frequency range including a frequency band different from the first to fourth frequency bands described above. The first filter 60L and the second filter 60H each has two input/output parts (a first input/output part and a second input/output part). The first input/output part of each of the first filter 60L and the second filter 60H is connected to the antenna terminal 130 with the directional coupler 1 interposed therebetween. The second input/output part of the first filter 60L is connected to a common terminal of the switch 55. Hereinafter, the first input/output part of the first filter 60L and the first input/output part of the second filter 60H are collectively described as a first input/output part of the diplexer 60 on occasions.

The directional coupler 1 is configured in the same manner as in the directional coupler 1 in Embodiment 1. The directional coupler 1 extracts, as a detection signal from the sub line 3 electromagnetically coupled to the main line 2, part of a radio frequency signal (reception signal) flowing through a partial section (main line 2) of a signal path between the antenna terminal 130 and the first input/output part of the diplexer 60. The directional coupler 1 then outputs the extracted detection signal to the outside of the radio frequency module 100 (for example, the signal processing circuit 210) via the coupler output terminal 181.

Like the directional coupler 1 in Embodiment 1, the directional coupler 1 in Embodiment 3 includes the main line 2, the first and second sub lines 31 and 32, the termination circuit 4, the first phase shifter circuit 5, the first selector switch 6, the second selector switch 7, the end switch 8, and the connection terminals 91 to 93.

The first selector switch, the second selector switch 7, and the end switch 8 are provided in the switch 55 and are integrated with the switch 55. The connection terminal 91 is connected to the antenna terminal 130, and the connection terminal 92 is connected to the first input/output part of the diplexer 60. The main line 2 of the directional coupler 1 thus forms the partial section of the signal path between the antenna terminal 130 and the diplexer 60. The connection terminal 93 is connected to the coupler output terminal 181.

The switch 55 is an antenna switch and is formed from, for example, a switch IC. The switch 55 is a switch for performing switching between connection and non-connection between a signal path S0 reaching the antenna terminal 130 and each of a plurality of signal paths S1 to S4 respectively reaching a plurality of duplexers 61 to 64 (filters). The switch 55 thus performs switching between connection and non-connection between the signal path So reaching the antenna terminal 130 and each of the plurality of duplexers 61 to 64 (filters). As described above, the switch 55 is integrated with the first selector switch 6, the second selector switch 7, and the end switch 8.

In more detail, the switch 55 includes a common terminal 55a, the plurality of selection terminals 55b, 55c, 55d, and 55e, the common terminal 6a and the two selection terminals 6b and 6c of the first selector switch 6, the two terminals 7a and 7b of the second selector switch 7, and the common terminal 8a and the two selection terminals 8b and 8c of the end switch 8.

The common terminal 55a of the switch 55 is connected to the second input/output part of the first filter 60L, and the plurality of selection terminals 55b, 55c, 55d, and 55e of the switch 55 are respectively connected to the first input/output parts of the duplexers 61 to 64 with the matching circuits 71 to 74 interposed therebetween. The common terminal 6a of the switch 55 is connected to the first end 31a of the first sub line 31 of the directional coupler 1 (see FIG. 1). The selection terminal 6b of the switch 55 is connected to the selection terminal 8c of the switch 55. The selection terminal 6c of the switch 55 is connected to the first end 5a of the first phase shifter circuit 5 of the directional coupler 1 (see FIG. 1). The common terminal 8a of the switch 55 is connected to the termination circuit 4 of the directional coupler 1 (see FIG. 1). The selection terminal 8b of the switch 55 is connected to the selection terminal 6b of the switch 55. The selection terminal 8c of the switch 55 is connected to the first end 32a of the second sub line 32 of the directional coupler 1 (see FIG. 1). The terminal 7a of the switch 55 is connected to the second end 5b of the first phase shifter circuit 5 of the directional coupler 1 (see FIG. 1), and the terminal 7b of the switch 55 is connected to the second end 32b of the second sub line 32 of the directional coupler 1 (see FIG. 1).

According to Embodiment 3, the first selector switch 6, the second selector switch 7, and the end switch 8 of the directional coupler 1 are integrated with the switch 55 (antenna switch), and thus it is possible to downsize the radio frequency module 100.

Embodiments 1 to 3 described above and the modifications thereof may be implemented in combination.

### Aspects

The embodiments and the modifications heretofore described disclose the following aspects.

A directional coupler (1 and 1B) according to a first aspect includes a main line (2), a first sub line (31), a second sub line (32), a termination circuit (4 and 4B), a first phase shifter circuit (5), a first selector switch (6), and a second selector switch (7). The termination circuit (4 and 4B) terminates one of the first sub line (31) and the second sub line (32). The first phase shifter circuit (5) is disposed on a first signal path (R1) between the first sub line (31) and the second sub line (32). The first selector switch (6) performs switching between connection and non-connection between the first sub line (31) and the first phase shifter circuit (5). The second selector switch (7) performs switching between connection and non-connection between the first phase shifter circuit (5) and the second sub line (32).

According to the configuration, in a first mode in which part of a first signal in a first frequency band that flows through the main line (2) is extracted from the sub line (3), the first selector switch (6) causes non-connection between the first sub line (31) and the first phase shifter circuit (5), and the second selector switch (7) causes non-connection between the first phase shifter circuit (5) and the second sub line (32). This enables a sub line formed from one of the first sub line (31) and the second sub line (32) to be used as the sub line (3) described above. In a second mode in which part of a second signal in a second frequency band (a frequency band lower than the first frequency band) flowing through the main line (2) is extracted from the sub line (3), the first selector switch (6) connects the first sub line (31) and the first phase shifter circuit (5), and the second selector switch (7) connects the first phase shifter circuit (5) and the second sub line (32). This enables a series circuit in which the first phase shifter circuit (5) is connected between the first sub line (31) and the second sub line (32) to be used as the sub line (3) described above.

As described above, in the sub line (3) used in the second mode, it is possible to connect the first phase shifter circuit (5) between the first sub line (31) and the second sub line (32). Accordingly, the first phase shifter circuit (5) enables a frequency characteristic to be changed for a signal flowing through the sub line (3) described above. In the second mode, it is thereby possible to prevent loss (insertion loss G3a) from occurring in the first signal (detection-excluded signal) when part of the second signal (detection-targeted signal) of the first signal in the first frequency band and the second signal in the second frequency band is extracted from the sub line (3), the first signal flowing through the main line (2), the first signal and the second signal simultaneously flowing through the main line (2), the loss being caused by leakage, to the sub line (3), of part of the first signal flowing through the main line (2). It is thus possible to prevent loss from occurring in the first signal (detection-excluded signal) flowing through the main line (2) when part of the second signal (detection-targeted signal) of the first signal and the second signal that simultaneously flow through the main line (2) is extracted from the sub line (3).

In the directional coupler (1) according to a second aspect, in the first aspect, the first phase shifter circuit (5) includes a low pass filter.

According to the configuration, in the sub line (3) used in the second mode, it is possible to prevent loss (insertion loss G2) occurring in the second signal serving as the detection-targeted signal from increasing.

In the directional coupler (1) according to a third aspect, in the second aspect, the first phase shifter circuit (5) includes a circuit component (variable capacitor (5k and 5m and 5n, 5p, and 5q)) with a variable characteristic value.

According to the configuration, it is possible to perform fine adjustment of a frequency characteristic of the degree of coupling between the sub line (3) used in the second mode and the main line (2) by controlling the characteristic value of the circuit component (variable capacitor (5k and 5m and 5n, 5p, and 5q)). It is thereby possible to prevent the occurrence of loss (insertion loss G3a) in the first signal (detection-excluded signal) flowing through the main line (2) when part of the second signal (detection-targeted signal) of the first signal and the second signal that simultaneously flow through the main line (2) is extracted from the sub line (3). In addition, even if the frequency characteristic of the degree of coupling between the sub line (3) and the main line (2) is changed due to a change in the impedance or the like of the sub line (3) in the second mode, it is possible to easily control the frequency characteristic of the degree of coupling described above by controlling the characteristic value of the first circuit component (variable capacitor (5k and 5m and 5n, 5p, and 5q)).

In the directional coupler (1) according to a fourth aspect, in the first or second aspect, the termination circuit (4) includes a circuit component with a variable characteristic value (a variable resistor (4a) and a variable capacitor (4b)).

According to the configuration, it is possible to accurately control the directivity of the directional coupler (1) by controlling the circuit component (the characteristic value of the variable resistor (4a) and the variable capacitor (4b)).

In the directional coupler (1) according to a fifth aspect, in any one of the first to fourth aspects, the termination circuit (4) has a circuit component of at least one of the resistor (4a) or the capacitor (4b) and the inductor (4c). The inductor (4c) is connected in series to the circuit component described above.

According to the configuration, the use of the inductor (4c) described above enables a change in directivity (directivity) of the directional coupler (1) to be improved, the change occurring in the case where the first phase shifter circuit (5) is connected between the first sub line (31) and the second sub line (32).

In any one of the first to fifth aspects, the directional coupler (1) according to a sixth aspect further includes a third sub line (33), a second phase shifter circuit (20), a third selector switch (21), and a fourth selector switch (22). The second phase shifter circuit (20) is disposed on a second signal path (R2) between the second sub line (32) and the third sub line (33). The third selector switch (21) performs switching between connection and non-connection between the second sub line (32) and the second phase shifter circuit (20). The fourth selector switch (22) performs switching between connection and non-connection between the second phase shifter circuit (20) and the third sub line (33). The termination circuit (4) terminates one of the first sub line (31), the second sub line (32), and the third sub line (33).

According to the configuration, in a third mode in which the third signal in a third frequency band lower than the second frequency band that flows through the main line (2) is extracted from the sub line (3), for example, switching all of the first to fourth selector switches (6, 7, 21, and 22) to a connection state enables, to be used as the sub line (3) described above, a series circuit in which the first sub line (31) is connected between the second sub line (32) and the first phase shifter circuit (5) and the second sub line (32) is connected between the third sub line (33) and the second phase shifter circuit (20). As described above, further including the third sub line (33), the second phase shifter circuit (20), the third selector switch (21), and the fourth selector switch (22) enables signals in a plurality of (for example, three) frequency bands to be extracted from the sub line (3). Also in this case, in the third mode in which part of the third signal (detection-targeted signal) among the signals in the plurality of frequency bands described above that simultaneously flow through the main line (2) is extracted from the sub line (3), it is possible to prevent loss from occurring in signals (the first signal and the second signal (detection-excluded signals)) in a frequency band higher than that of the third signal flowing through the main line (2).

In the directional coupler (1) according to a seventh aspect, in the sixth aspect, the second phase shifter circuit (20) has a characteristic different from a characteristic of the first phase shifter circuit (5).

According to the configuration, it is possible to improve the degree of freedom in fine adjustment of a frequency characteristic of the degree of coupling between the sub line (3) and the main line (2) that are used in the third mode.

In any one of the first to seventh aspects, the directional coupler (1) according to an eighth aspect includes a multilayer substrate (10) and an IC chip (13). The main line (2) is provided inside the multilayer substrate (10). The IC chip (13) includes the first phase shifter circuit (5). The IC chip (13) is disposed on a main surface (101) of the multilayer substrate (10).

According to the configuration, the first phase shifter circuit (5) is integrated with the IC chip (13), and it is thus possible to dispose the first phase shifter circuit (5) physically away from the main line (2) disposed inside the multilayer substrate (10). This enables avoidance of optional coupling between the first phase shifter circuit (5) and the main line (2). If the IC chip (13) is integrated with the first phase shifter circuit (5), the first selector switch (6), and the second selector switch (7), the first phase shifter circuit (5) is disposed in proximity to the first selector switch (6) and the second selector switch (7). This enables a connection distance between the first phase shifter circuit (5) and each of the first selector switch (6) and the second selector switch (7) to be reduced. It is thereby possible to control the phase of the sub line (3) with high accuracy.

In the directional coupler (1) according to a ninth aspect, in the eighth aspect, the IC chip (13) overlaps with the main line (2) in plan view in a thickness direction (D1) of the multilayer substrate (10).

According to the configuration, it is possible to reduce the connection distance between the IC chip (13) and the main line (2) and prevent an optional inductor from being generated on wiring connecting the IC chip (13) and the main line (2).

A radio frequency module (100) according to a tenth aspect includes the directional coupler (1) according to any one of the first to ninth aspects, an antenna terminal (130), a plurality of filters (61), and an antenna switch (55). The antenna switch (55) performs switching between connection and non-connection between a third signal path (S0) reaching the antenna terminal (130) and each of the plurality of filters (61 to 64). The main line (2) of the directional coupler (1) forms a partial section of the third signal path (S0).

According to the configuration, it is possible to provide a radio frequency module (100) including the directional coupler (1).

In the radio frequency module (100) according to an eleventh aspect, in the tenth aspect, the antenna switch (55) is integrated with the first selector switch (6) and the second selector switch (7) of the directional coupler (1).

According to the configuration, it is possible to downsize the radio frequency module (100).

A communication apparatus (200) according to a twelfth aspect includes the radio frequency module (100) according to the eleventh aspect and a signal processing circuit (210). The signal processing circuit (210) is connected to the radio frequency module (100) and performs signal processing of a radio frequency signal.

According to the configuration, it is possible to provide the communication apparatus (200) including the radio frequency module (100) having the actions and effects described above.

### REFERENCE SIGNS LIST

1, 1B directional coupler
2 main line
2a first end
2b second end
3 sub line
4, 4B termination circuit
4a variable resistor
4b variable capacitor
4c inductor
4d switch
5, 5B first phase shifter circuit
5a first end
5b second end
5c inductor
5d, 5e, 5h, 5i, 5j capacitor
5f, 5g inductor
5k, 5m, 5n, 5p, 5q variable capacitor
6 first selector switch
6a common terminal
6b, 6c selection terminal
7 second selector switch
7a, 7b terminal
8 end switch
8a common terminal
8b, 8c, 8d selection terminal
9 connection terminal
10 mounting substrate (multilayer substrate)
10a first layer
10b second layer
10c third layer
10d fourth layer
10e fifth layer
13 IC chip
16 first resin layer
17 metal electrode layer
20 second phase shifter circuit
20a first end
20b second end
21 third selector switch
21a common terminal
21b, 21c selection terminal
22 fourth selector switch
22a, 22b terminal
31 first sub line
31a first end
31b second end
32 second sub line
32a first end
32b second end
33 third sub line
33a first end
33b second end
51 to 54 switch
55 antenna switch
55a common terminal
55b to 55e selection terminal
60 diplexer
60H second filter
60L first filter
61 to 64 duplexer (filter)
61R to 64T reception filter
61T to 64T transmission filter
71 to 74 matching circuit
91 first connection terminal
92 second connection terminal
93 third connection terminal
100 radio frequency module
101 first main surface
103 to 106 terminal
110 external connection terminals
111, 112 signal input terminal
121, 122 signal output terminal
130 antenna terminal
131, 132 output matching circuit
141, 142 matching circuit
151, 152 power amplifier
161, 162 low noise amplifier
181 coupler output terminal
200 communication apparatus
210 signal processing circuit
211 RF signal processing circuit
212 baseband signal processing circuit
220 antenna
300 directional coupler
D1 direction
G1 to G3, G3a insertion loss
L1 to L3 line length
R1 first signal path
R2 second signal path
S0 third signal path
S1 to S4 fourth signal path

1. A directional coupler comprising:
a main line;
a first sub line;
a second sub line;
a termination circuit configured to terminate the first sub line or the second sub line;
a first phase shifter circuit in a first signal path between the first sub line and the second sub line;
a first selector switch configured to selectively switch between connection and non-connection between the first sub line and the first phase shifter circuit; and
a second selector switch configured to selectively switch between connection and non-connection between the first phase shifter circuit and the second sub line.

2. The directional coupler according to claim 1, wherein the first phase shifter circuit comprises a low pass filter.

3. The directional coupler according to claim 2, wherein the first phase shifter circuit comprises a circuit component with a variable characteristic value.

4. The directional coupler according to claim 1, wherein the termination circuit comprises a circuit component with a variable characteristic value.

5. The directional coupler according to claim 1,
wherein the termination circuit comprises:
a resistor or a capacitor, and
an inductor, and
wherein the inductor is connected in series to the resistor or the capacitor.

6. The directional coupler according to claim 1, further comprising:
a third sub line;
a second phase shifter circuit in a second signal path between the second sub line and the third sub line;
a third selector switch configured to selectively switch between connection and non-connection between the second sub line and the second phase shifter circuit; and
a fourth selector switch configured to selectively switch between connection and non-connection between the second phase shifter circuit and the third sub line,
wherein the termination circuit is configured to terminate the first sub line, the second sub line, or the third sub line.

7. The directional coupler according to claim 6, wherein the second phase shifter circuit has a characteristic different from a characteristic of the first phase shifter circuit.

8. The directional coupler according to claim 1, further comprising:
a multilayer substrate, the main line being inside the multilayer substrate; and
an integrated circuit (IC) chip comprising the first phase shifter circuit,
wherein the IC chip is on a main surface of the multilayer substrate.

9. The directional coupler according to claim 8, wherein in plan view in a thickness direction of the multilayer substrate, the IC chip overlaps with the main line.

10. A radio frequency module comprising:
the directional coupler according to claim 1;
an antenna terminal;
a plurality of filters; and
an antenna switch configured to selectively switch between connection and non-connection between a third signal path reaching the antenna terminal and each of the plurality of filters,
wherein the main line of the directional coupler forms a partial section of the third signal path.

11. The radio frequency module according to claim 10, wherein the antenna switch is integrated with the first selector switch and the second selector switch of the directional coupler.

12. A communication apparatus comprising:
the radio frequency module according to claim 11; and
a signal processing circuit that is connected to the radio frequency module and that is configured to perform signal processing of a radio frequency signal.
